(19) United States
(12) Patent Application Publication
(10) Pub. No.: US 2026/0107403 A1
(43) Pub. Date: Apr. 16, 2026

(54) CABLE BACKPLANE AND COMMUNICATION DEVICE

(71) Applicant: Dongguan Luxshare Technologies Co., Ltd, Dongguan City (CN)

(72) Inventors: Feng ZHENG, Dongguan City (CN); Tao SONG, Dongguan City (CN); Hongji CHEN, Dongguan City (CN); Zhongfan GOU, Dongguan City (CN); Xingyu LI, Dongguan City (CN)

(73) Assignee: Dongguan Luxshare Technologies Co., Ltd, Dongguan City (CN)

(21) Appl. No.: 19/025,539

(22) Filed: Jan. 16, 2025

(30) Foreign Application Priority Data
Oct. 10, 2024 (CN) 202411411858.7

(51) Int. Cl. H05K 7/14

(52) U.S. Cl. CPC H05K 7/1454; H05K 7/1491

(57) ABSTRACT

Provided are a cable backplane and a communication device, relating to the field of communication technologies. The cable backplane includes a panel and connector modules. The panel is provided with multiple mounting holes. Multiple connector modules are in one-to-one correspondence with the multiple mounting holes. Each connector module includes a support assembly, a connector body, and a floating assembly. The support assembly is provided with an assembly hole connecting with the mounting hole. The connector body passes through the corresponding mounting hole and the corresponding assembly hole. The support assembly is floatingly connected to the panel in the first direction and the second direction via the floating assembly, and the connector body is floatingly connected to the support assembly in the third direction via the floating assembly so that the connector body can float relative to the panel in the first direction, the second direction, and the third direction.

### CROSS-REFERENCE TO RELATED APPLICATION

The present application claims priority to Chinese Patent Application No. 2024114118587 filed with the China National Intellectual Property Administration (CNIPA) on Oct. 10, 2024, the disclosure of which is incorporated herein by reference in its entirety.

### TECHNICAL FIELD

The present disclosure relates to the field of communication technologies and, in particular, to a cable backplane and a communication device.

### BACKGROUND

Communication systems, such as network systems, servers, and data centers, use a large number of printed circuit boards (referred to as backplanes) to interconnect midplanes, daughter cards, line cards, and/or switch cards. With the rapid development of communication technologies, the requirements for the signal transmission rate and the differential pair unit density are getting higher and higher, and the interconnection solution between the cable backplane and the connector on the plug-in box of the cabinet has become a trend.

In the related art, the cable backplane generally includes a backplane body and connectors fixedly connected to the backplane body. Since the connectors on the backplane body are fixedly disposed on the backplane body and the connectors on the plug-in box of the cabinet are also fixedly connected to the plug-in box of the cabinet, the connectors on the cable backplane cannot move relative to the backplane body, resulting in the problem that the connectors of the cable backplane in the related art cannot simultaneously mate with multiple connectors on the plug-in box through insertion and leading to lower reliability.

### SUMMARY

An object of the present disclosure is to provide a cable backplane and a communication device to solve the technical problems of low reliability and difficult insertion in the related art.

According to the preceding concept, the present disclosure adopts the technical solutions below.

The cable backplane includes a panel and connector modules.

The panel is provided with multiple mounting holes.

Multiple connector modules are provided in one-to-one correspondence with the multiple mounting holes, where each connector module includes a support assembly, a connector body, and a floating assembly, the support assembly is provided with an assembly hole connecting with the mounting hole, the connector body passes through the corresponding mounting hole and the corresponding assembly hole, the support assembly is floatingly connected to the panel in a first direction and a second direction via the floating assembly, and the connector body is floatingly connected to the support assembly in a third direction via the floating assembly so that the connector body is capable of floating relative to the panel in the first direction, the second direction, and the third direction.

The first direction, the second direction, and the third direction are perpendicular to each other.

Optionally, the floating assembly includes a first floating module and a second floating module, the first floating module is connected to the panel and the support assembly, and the support assembly floats relative to the panel in the first direction and the second direction via the first floating module.

The second floating modules are connected to the support assembly and the connector body, and the connector body floats relative to the support assembly in the third direction via the second floating modules, where the third direction is the thickness direction of the panel.

Optionally, the support assembly includes a base plate and a cover plate, the base plate is disposed on a side of the panel, the cover plate is disposed on a side of the base plate facing away from the panel and movably connected to the base plate, the assembly hole includes a first assembly hole disposed on the base plate and a second assembly hole disposed on the cover plate, and the connector body is limited between the base plate and the panel in the third direction.

The first floating module includes a movable hole and a first connector, where the movable hole is disposed on the base plate, the first connector passes through the movable hole and is connected to the panel, and the first connector limits the movement of the base plate relative to the panel in the third direction.

The length of the portion of the first connector located in the movable hole in the first direction is a first length, the length of the movable hole in the first direction is a second length, the first length is less than the second length, the length of the portion of the first connector located in the movable hole in the second direction is a third length, the length of the movable hole in the second direction is a fourth length, and the third length is less than the fourth length.

Optionally, the first connector and the movable hole are coaxially arranged.

Optionally, the support assembly includes a base plate and a cover plate, the base plate is disposed on a side of the panel, the cover plate is disposed on a side of the base plate facing away from the panel and movably connected to the base plate, the assembly hole includes a first assembly hole disposed on the base plate and a second assembly hole disposed on the cover plate, and the connector body is limited between the base plate and the panel in the third direction.

The second floating module includes a second connector, an elastic member, and a floating through hole, where the floating through hole is provided on the cover plate, the second connector is capable of sliding through the floating through hole and being connected to the base plate, the position of the base plate relative to the panel in the third direction is fixed, the elastic member is sleeved on the second connector, an end of the elastic member abuts against the cover plate, and the other end of the elastic member is limited by the second connector.

Optionally, the support assembly includes a base plate and a cover plate, the base plate is disposed on a side of the panel, the cover plate is disposed on a side of the base plate facing away from the panel and movably connected to the base plate, the assembly hole includes a first assembly hole disposed on the base plate and a second assembly hole disposed on the cover plate, and the connector body is limited between the base plate and the panel in the third direction.

The base plate includes an installation region and two connection regions, where the two connection regions are located on two sides of the installation region in the first direction, the first assembly hole is disposed in the installation region, the cover plate and the installation region are opposite to each other, two side surfaces of the cover plate are correspondingly flush with two side surfaces of the base plate in the second direction, multiple first floating modules are provided, and at least one first floating module is disposed in each of the two connection regions.

Optionally, multiple second floating modules are provided on two sides of the second assembly hole in the second direction and are all connected to the cover plate.

Optionally, the cable backplane further includes vertical plate assemblies connected to the panel and used for connecting the panel to a cabinet body of a communication device.

Optionally, the cable backplane further includes a housing mounted on a side of the panel, where the vertical plate assemblies are located in the housing, the vertical plate assembly is provided with first threaded holes, the housing is provided with first through holes connecting with the first threaded holes, an end of a first bolt passes through the first through hole and is screwed to the first threaded hole, and the other end of the first bolt is connected to the cabinet body of a cabinet.

A communication device includes the preceding cable backplane.

The present disclosure has the beneficial effects below.

In the cable backplane and the communication device provided in the present disclosure, the connector module includes the support assembly, the connector body, and the floating assembly. The support assembly is floatingly connected to the panel in the first direction and the second direction through the floating assembly so that the support assembly can move slightly relative to the panel in the first direction and the second direction, the position deviation of the mating movable connector in the first direction and the second direction can be compensated, and the connector body and the corresponding movable connector can be smoothly aligned in the third direction and smoothly connected through insertion. The connector body is floatingly connected to the support assembly so that the position deviation of the movable connector in the third direction can be compensated, it can be ensured that the connector bodies and the corresponding movable connectors can be connected in place through insertion, the problem that the communication quality is affected due to incomplete insertion can be avoided, the cable backplane can accommodate the larger position deviation of the movable connector, the position deviation requirements for the movable connectors on the plug-in box can be lowered, and it can be ensured to a greater extent that multiple connector bodies and multiple movable connectors are connected in place simultaneously through insertion with higher versatility, flexibility, and reliability.

### BRIEF DESCRIPTION OF DRAWINGS

To illustrate technical solutions in embodiments of the present disclosure more clearly, the drawings used in the description of the embodiments of the present disclosure are briefly described below. Apparently, the drawings described below illustrate only part of the embodiments of the present disclosure, and those of ordinary skill in the art may obtain other drawings based on the content of the embodiments of the present disclosure and the drawings on the premise that no creative work is done.

FIG. 1 is a first view illustrating the structure of a cable backplane according to an embodiment of the present disclosure.

FIG. 2 is a second view illustrating the structure of a cable backplane according to an embodiment of the present disclosure.

FIG. 3 is an exploded view of a cable backplane according to an embodiment of the present disclosure.

FIG. 4 is a view illustrating the structure of a panel according to an embodiment of the present disclosure.

FIG. 5 is a view illustrating the structure of part of a cable backplane according to an embodiment of the present disclosure.

FIG. 6 is a first sectional view of a cable backplane according to an embodiment of the present disclosure.

FIG. 7 is a second sectional view of a cable backplane according to an embodiment of the present disclosure.

FIG. 8 is a first view illustrating the structure of a connector module according to an embodiment of the present disclosure.

FIG. 9 is an exploded view of a connector module according to an embodiment of the present disclosure.

FIG. 10 is a second view illustrating the structure of a connector module according to an embodiment of the present disclosure.

FIG. 11 is a first sectional view of a connector module according to an embodiment of the present disclosure.

FIG. 12 is a second sectional view of a connector module according to an embodiment of the present disclosure.

FIG. 13 is a schematic view illustrating that a connector module and a movable connector mate with each other through insertion according to an embodiment of the present disclosure.

FIG. 14 is a schematic view of step-by-step guidance performed by guide members according to an embodiment of the present disclosure.

FIG. 15 is a sectional view of a panel according to an embodiment of the present disclosure.

FIG. 16 is a view illustrating the structure of a plate according to an embodiment of the present disclosure.

FIG. 17 is a view illustrating the structure of another plate according to an embodiment of the present disclosure.

FIG. 18 is a partial structural view of a housing according to an embodiment of the present disclosure.

FIG. 19 is a first view illustrating the structure of a vertical plate according to an embodiment of the present disclosure.

FIG. 20 is a second view illustrating the structure of a vertical plate according to an embodiment of the present disclosure.

FIG. 21 is a schematic view illustrating the assembly of a vertical plate and a panel according to an embodiment of the present disclosure.

FIG. 22 is a sectional view illustrating the assembly of a vertical plate and a panel according to an embodiment of the present disclosure.

FIG. 23 is a view illustrating the structure of a cabinet according to an embodiment of the present disclosure.

FIG. 24 is a schematic view illustrating that two cable backplanes and one plug-in box mate with each other through insertion according to an embodiment of the present disclosure.

FIG. 25 is a view illustrating the structure of a cable backplane with heat dissipation holes according to an embodiment of the present disclosure.

### REFERENCE LIST

100 panel
110 mounting hole
120 plate
1201 middle region
1202 frame region
121 first connecting portion
1211 pre-mounted groove
1212 positioning hole
1213 through hole
122 second connecting portion
1221 pre-mounted protrusion
1222 second threaded hole
123 body portion
124 shallow groove
1241 third threaded hole
12a first plate
12b second plate
12c third plate
130 positioning pin
140 third through hole
141 large hole section
142 small hole section
150 fifth through hole
160 third connector
200 connector module
210 support assembly
211 base plate
2111 first assembly hole
2112 installation region
2113 connection region
2114 first groove
212 cover plate
2121 second assembly hole
213 connector body
2131 limiting portion
214 guide member
2141 first guide section
2142 second guide section
2143 tapered section
2144 transition inclined plane
220 floating assembly
221 first floating module
2211 movable hole
2212 first connector
22121 smooth rod section
22122 threaded section
22123 cross nut
222 second floating module
2221 second connector
2222 elastic member
2223 floating through hole
300 vertical plate assembly
310 vertical plate
311 first threaded hole
320 positioning column
330 fourth threaded hole
340 supporting protrusion
350 protruding column
360 fifth threaded hole
370 hollow
400 housing
410 first through hole
420 opening
430 second through hole
440 fourth through hole
450 tab
451 tab through hole
460 heat dissipation hole
500 movable connector
510 fixing pate
511 guide hole
5111 tapered hole section
5112 pilot hole section
520 connector body portion
600 handle
10 cable backplane
20 cabinet body
30 plug-in box
X first direction
Y second direction
Z third direction

### DETAILED DESCRIPTION

To make the solved technical problems, adopted technical solutions, and achieved technical effects of the present disclosure more apparent, the technical solutions of the present disclosure are further described hereinafter in conjunction with the drawings and embodiments. It is to be understood that the embodiments described herein are intended to illustrate and not to limit the present disclosure. Additionally, it is to be noted that for ease of description, only part, not all, of structures related to the present disclosure are illustrated in the drawings.

It is to be noted that similar reference numerals and letters represent similar items in the drawings. Therefore, once an item is defined in one drawing, the item no longer needs to be defined and interpreted in the subsequent drawings.

In the description of the present disclosure, terms “joined”, “connected”, and “fixed” are to be understood in a broad sense unless otherwise expressly specified and limited. For example, the term “connected” may refer to “fixedly connected”, “detachably connected”, or “integrated”, may refer to “mechanically connected” or “electrically connected”, may refer to “connected directly” or “connected indirectly through an intermediary”, or may refer to “connected inside two elements” or “an interaction relation between two elements”. For those of ordinary skill in the art, specific meanings of the preceding terms in the present disclosure may be understood based on specific situations.

In the present disclosure, unless otherwise expressly specified and limited, when a first feature is described as “above” or “below” a second feature, the first feature and the second feature may be in direct contact, or the first feature and the second feature may be in contact via another feature between the two features instead of being in direct contact. Moreover, when the first feature is described as “on”, “above”, or “over” the second feature, the first feature is right on, above, or over the second feature, the first feature is obliquely on, above, or over the second feature, or the first feature is simply at a higher level than the second feature. When the first feature is described as “under”, “below”, or “underneath” the second feature, the first feature is right under, below, or underneath the second feature, the first feature is obliquely under, below, or underneath the second feature, or the first feature is simply at a lower level than the second feature. In the description of the embodiments herein, “multiple” means two or more unless otherwise specified.

In the description of this embodiment, orientations or position relations indicated by terms such as “upper”, “lower”, and “right” are based on the drawings. These orientations or position relations are intended only to facilitate description and simplify operations and not to indicate or imply that a device or element referred to must have such particular orientations or must be configured or operated in such particular orientations. Thus, these orientations or position relations are not to be construed as limiting the present disclosure. In addition, the terms “first” and “second” are only used for distinguishing between descriptions and have no special meanings.

It is to be noted that when a component is described as being “fixed to” or “disposed on” another component, the component may be directly on the particular component or an intervening component may be on the particular component.

Technical solutions in the present disclosure are further described below in conjunction with the drawings and embodiments.

In a first aspect, this embodiment provides a cable backplane with high versatility and reliability.

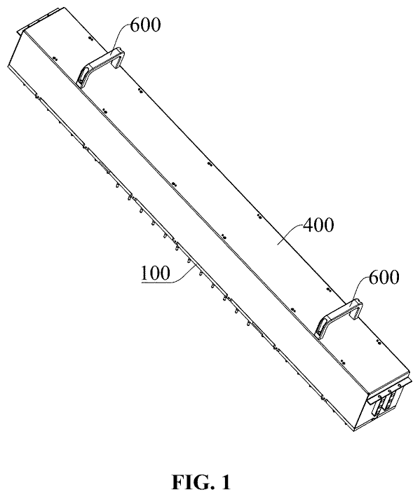

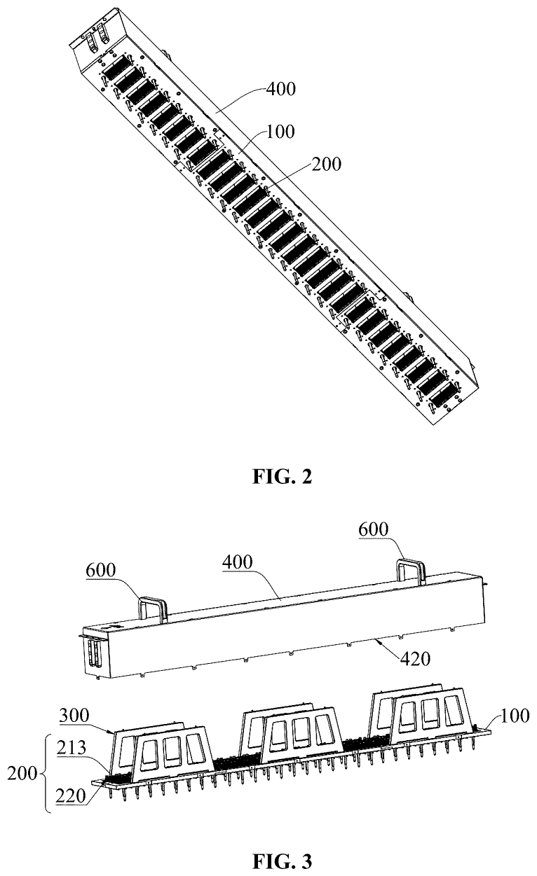

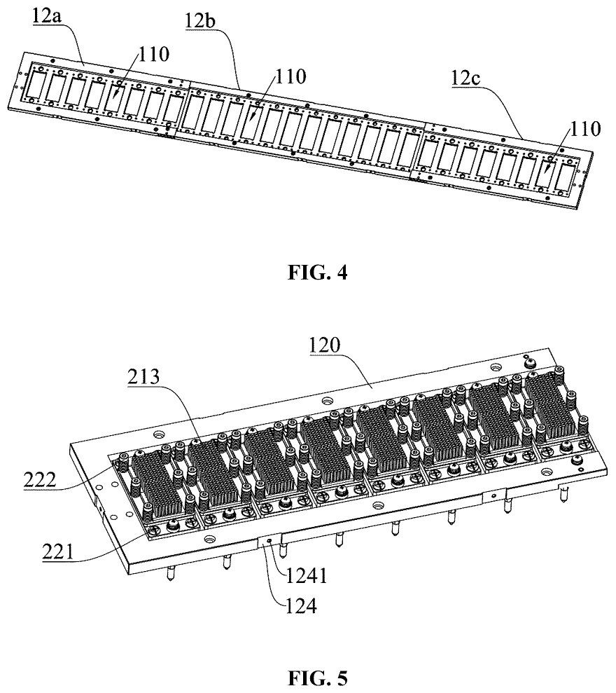

As shown in FIGS. 1 to 3, a cable backplane 10 includes a panel 100 and connector modules 200. The panel 100 is used for mounting the connector modules 200. Specifically, as shown in FIG. 4, the panel 100 is provided with multiple mounting holes 110. For example, the panel 100 in this embodiment is rectangular. For ease of description, this embodiment defines a first direction X, a second direction Y, and a third direction Z. The first direction X is the width direction of the panel 100, the second direction Y is the length direction of the panel 100, and the third direction Z is the thickness direction of the panel 100. Generally, the first direction X, the second direction Y, and the third direction Z are perpendicular to each other. In this embodiment, the length of the panel 100 is greater than the width of the panel 100, and the width of the panel 100 is greater than the thickness of the panel 100. Of course, it is to be understood that the panel 100 may be in other shapes, such as a square or an irregular shape, which is not limited in this embodiment.

In this embodiment, the multiple mounting holes 110 are arranged at intervals along the second direction Y. For example, the multiple mounting holes 110 may be arranged at equal intervals. The shapes of the mounting holes 110 may be set according to actual requirements. For example, the mounting holes 110 in this embodiment are rectangular.

For example, multiple connector modules 200 are provided in one-to-one correspondence with the multiple mounting holes 110, and each connector module 200 can be mounted in the corresponding mounting hole 110. Specifically, as shown in FIGS. 3 to 8, each connector module 200 includes a support assembly 210, a connector body 213, and a floating assembly 220. Each support assembly 210 is provided with an assembly hole (not shown in the figure) connecting with the corresponding mounting hole 110, the connector body 213 passes through the corresponding mounting hole 110 and the corresponding assembly hole, and the support assembly 210 is floatingly connected to the panel 100 in the first direction X and the second direction Y via the floating assembly 220 so that the support assembly 210 can float relative to the panel 100 in the first direction X and the second direction Y. The connector body 213 is floatingly connected to the support assembly 210 in the third direction Z via the floating assembly 220 so that the connector body 213 can float relative to the support assembly 210 in the third direction Z.

It is to be noted that the floating connection between the support assembly 210 and the panel 100 may be understood as that the support assembly 210 can move slightly relative to the panel 100. Specifically, the support assembly 210 can move slightly relative to the panel 100 in the first direction X and the second direction Y. Similarly, the floating connection between the connector body 213 and the support assembly 210 may be understood as that the connector body 213 can move slightly relative to the support assembly 210 in the third direction Z so that the connector body 213 is not fixed relative to the panel 100 but can move slightly relative to the panel 100 in the first direction X, the second direction Y, and the third direction Z. The length of the small-amplitude movement in this embodiment may be 3 mm, 5 mm, 8 mm, 10 mm, 15 mm, 20 mm, or the like, which is not limited in this embodiment. For example, the third direction Z in this embodiment is a plugging and unplugging direction of the connector body 213 and a mating connector (which may be named as a movable connector 500).

When the cable backplane 10 provided in this embodiment is used, the connector for mating with the connector module 200 on the cable backplane 10 is referred to as the movable connector 500. The movable connector 500 is disposed on a plug-in box 30, and the plug-in box 30 is provided with multiple movable connectors 500. The movable connectors 500 are aligned with connector bodies 213. At this time, if some movable connectors 500 cannot be directly aligned with the connector bodies 213, the connector bodies 213 are pushed by the movable connectors 500 to move slightly in the first direction X and/or the second direction Y so that the connector bodies 213 can be smoothly aligned with the movable connectors 500. When the movable connector 500 exceeding other movable connectors 500 in the plugging and unplugging direction exists on the plug-in box 30, if the protruding movable connector 500 and the corresponding connector body 213 are connected in place through insertion, other movable connectors 500 and the corresponding connector bodies 213 cannot be connected in place through insertion. In this embodiment, the connector body 213 is floatingly connected to the support assembly 210 through the floating assembly 220 so that the protruding movable connector 500 can continue to push the connector body 213 to move in the third direction Z until other non-protruding movable connectors 500 and the corresponding connector bodies 213 can be connected in place through insertion.

In the cable backplane 10 provided in this embodiment, the connector module 200 includes the support assembly 210, the connector body 213, and the floating assembly 220. The support assembly 210 is floatingly connected to the panel 100 in the first direction X and the second direction Y through the floating assembly 220 so that the support assembly 210 can move slightly relative to the panel 100 in the first direction X and the second direction Y, the position deviation of the mating movable connector 500 in the first direction X and the second direction Y can be compensated, and the connector body 213 and the corresponding movable connector 500 can be smoothly aligned in the third direction Z and smoothly connected through insertion. The connector body 213 is floatingly connected to the support assembly 210 so that the position deviation of the movable connector 500 in the third direction Z can be compensated, it can be ensured that each set of the connector body 213 and the corresponding movable connector 500 can be connected in place through insertion, the problem that the communication quality is affected due to incomplete insertion can be avoided, the cable backplane 10 can accommodate the larger position deviation of the movable connector 500, the position deviation requirements for the movable connectors 500 on the plug-in box 30 can be lowered, and it can be ensured to a greater extent that multiple connector bodies 213 and multiple movable connectors 500 are connected in place simultaneously through insertion with higher versatility, flexibility, and reliability.

For example, as shown in FIG. 5, the floating assembly 220 includes first floating modules 221 and second floating modules 222. The first floating modules 221 are connected to the panel 100 and the support assembly 210, and the support assembly 210 floats relative to the panel 100 in the first direction X and the second direction Y via the first floating modules 221. The second floating modules 222 are connected to the support assembly 210 and the connector body 213, and the connector body 213 floats relative to the support assembly 210 in the third direction Z via the second floating modules 222, that is, the connector body 213 moves slightly relative to the panel 100 in the third direction Z via the second floating modules 222. The third direction Z is the thickness direction of the panel 100.

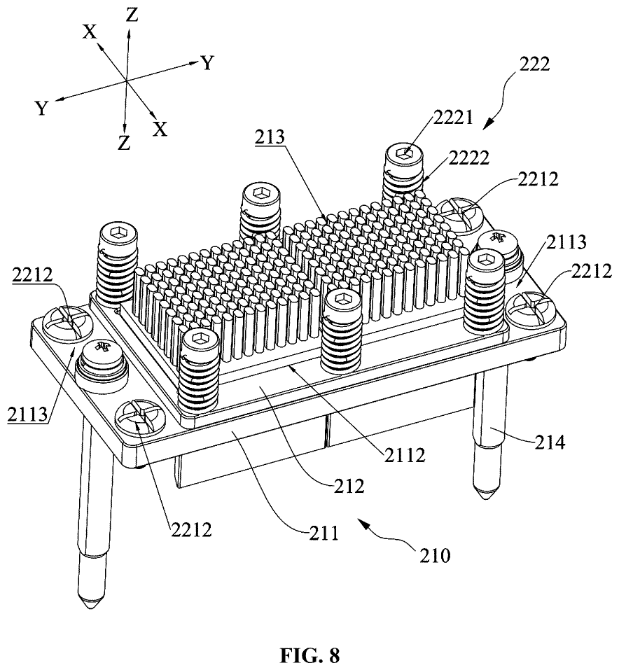

Further optionally, as shown in FIG. 8, the support assembly 210 includes a base plate 211 and a cover plate 212. The base plate 211 is disposed on a side of the panel 100. Specifically, the panel 100 has a front side and a back side which are opposite to each other in the thickness direction of the panel 100. The front side faces the movable connector 500, that is, the portion of the connector body 213 for connecting the movable connector 500 through insertion extends out from the front side. The base plate 211 in this embodiment is disposed on a side of the back side of the panel 100. The cover plate 212 is disposed on a side of the base plate 211 facing away from the panel 100. In this embodiment, the base plate 211, the panel 100, and the cover plate 212 are arranged in parallel. Moreover, the cover plate 212 is movably connected to the base plate 211. Specifically, the cover plate 212 can move relative to the base plate 211 in the third direction Z but cannot move relative to the base plate 211 in the second direction Y and the first direction X. The assembly hole includes a first assembly hole 2111 disposed on the base plate 211 and a second assembly hole 2121 disposed on the cover plate 212. In this embodiment, the connector body 213 is limited between the base plate 211 and the panel 100 in the third direction Z, that is, the movement of the connector body 213 in the third direction Z is limited by the base plate 211 and the panel 100.

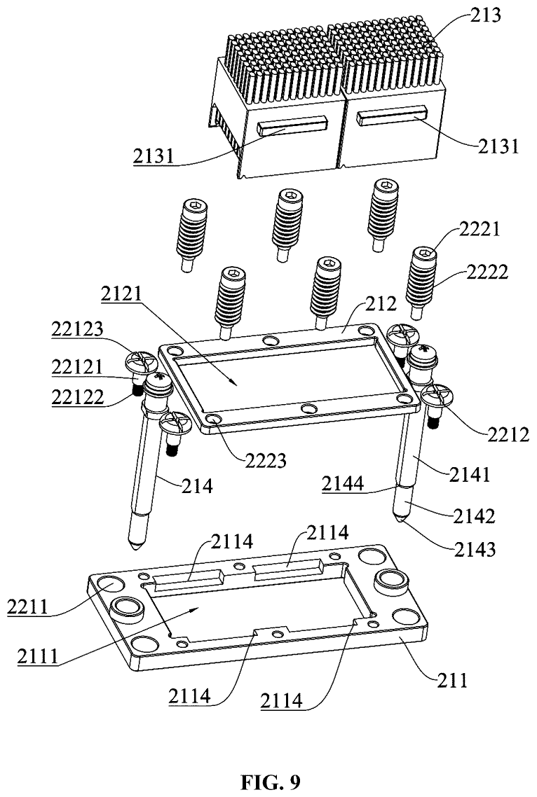

Referring to FIG. 9, the first floating module 221 includes a movable hole 2211 and a first connector 2212. The movable holes 2211 are disposed on the base plate 211 and penetrate the base plate 211 along the third direction Z. The first connectors 2212 pass through the movable holes 2211 and are connected to the panel 100, and the first connectors 2212 limit the movement of the base plate 211 relative to the panel 100 in the third direction Z so that the base plate 211 cannot move relative to the panel 100 in the third direction Z but can move relative to the panel 100 in the first direction X and the second direction Y.

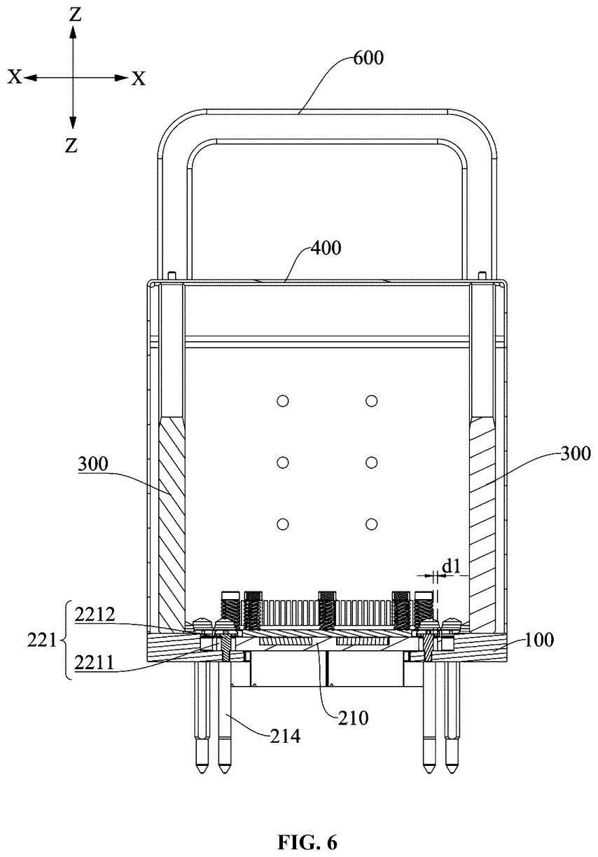

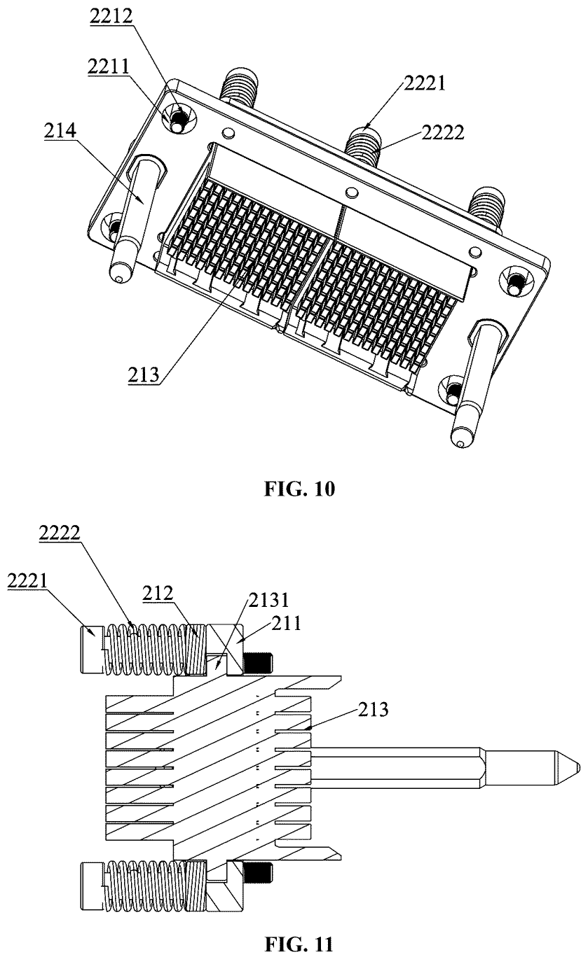

Specifically, as shown in FIGS. 6 and 10, the length of the portion of the first connector 2212 located in the movable hole 2211 in the first direction X is a first length, the length of the movable hole 2211 in the first direction X is a second length, and the first length is less than the second length so that the base plate 211 can move relative to the first connectors 2212 in the first direction X, thereby achieving the movement of the base plate 211 relative to the panel 100 in the first direction X and the movement of the connector body 213 relative to the panel 100 in the first direction X. It is to be noted that the movement limit of the base plate 211 in the first direction X is that the outer circumferential walls of the first connectors 2212 are in contact with the hole walls of the movable holes 2211, and at this time, the base plate 211 cannot continue moving relative to the first connectors 2212 in the first direction X. FIG. 6 shows that the minimum distance between the outer circumferential wall of the first connector 2212 and the hole wall of the movable hole 2211 in the first direction X is a first distance d1.

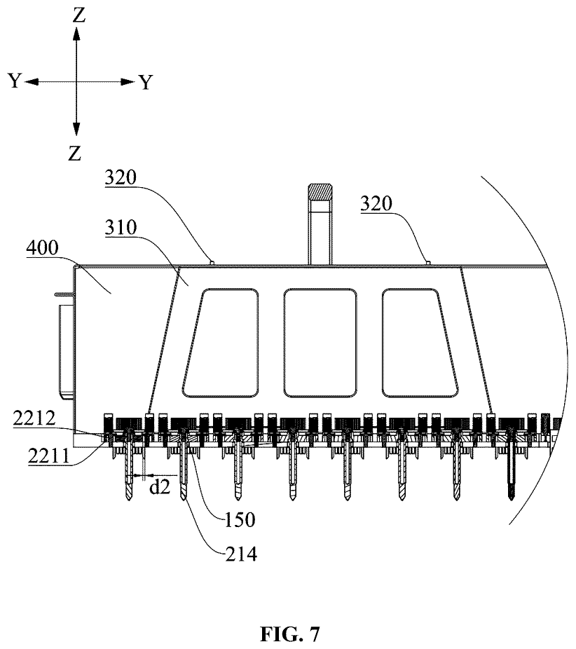

Moreover, as shown in FIGS. 7 and 10, the length of the portion of the first connector 2212 located in the movable hole 2211 in the second direction Y is a third length, the length of the movable hole 2211 in the second direction Y is a fourth length, and the third length is less than the fourth length so that the base plate 211 can move relative to the first connectors 2212 in the second direction Y, thereby achieving the movement of the base plate 211 relative to the panel 100 in the second direction Y and the movement of the connector body 213 relative to the panel 100 in the second direction Y. It is to be noted that the movement limit of the base plate 211 in the second direction Y is that the outer circumferential walls of the first connectors 2212 are in contact with the hole walls of the movable holes 2211, and at this time, the base plate 211 cannot continue moving relative to the first connectors 2212 in the second direction Y. FIG. 7 shows that the minimum distance between the outer circumferential wall of the first connector 2212 and the hole wall of the movable hole 2211 in the second direction Y is a second distance d2.

Optionally, as shown in FIG. 9, the first connector 2212 may be a Phillips equal height screw. Specifically, the Phillips equal height screw includes a smooth rod section 22121 and a threaded section 22122. A cross nut 22123 of the screw is located on a side of the base plate 211 facing away from the panel 100, the smooth rod section 22121 is inserted into the movable hole 2211, and the threaded section 22122 is screwed to the panel 100.

In some optional examples, the first connector 2212 and the movable hole 2211 are coaxially arranged so that an interval exists between the outer circumferential wall of the first connector 2212 and the hole wall of the movable hole 2211 in the circumferential direction of the first connector 2212, the base plate 211 can move to the left or right relative to the panel 100 in the direction shown in FIG. 6 by the first distance d1, and the base plate 211 can move to the left or right relative to the panel 100 in the direction shown in FIG. 7 by the second distance d2. In this manner, the flexibility of the base plate 211 and the connector body 213 can be further improved, and the cable backplane 10 can be adapted to different scenarios.

For example, as shown in FIG. 9, the second floating module 222 includes a second connector 2221, an elastic member 2222, and a floating through hole 2223. The floating through holes 2223 are provided on the cover plate 212, and the second connectors 2221 can slide through the floating through holes 2223 and be connected to the base plate 211 so that when the base plate 211 moves in the first direction X and the second direction Y, the base plate 211 can drive the cover plate 212 to move in the first direction X and the second direction Y through the second connectors 2221. It is to be noted that the position of the base plate 211 relative to the panel 100 in the third direction Z is fixed, that is, the base plate 211 does not move relative to the panel 100 in the third direction Z. The elastic member 2222 is sleeved on the second connector 2221, an end of the elastic member 2222 abuts against the cover plate 212, and the other end of the elastic member 2222 is limited by the second connector 2221. For example, a cap portion is provided at an end of the second connector 2221 facing away from the cover plate 212, and the elastic member 2222 may abut against the cap portion. The elastic member 2222 in this embodiment always tends to move the cover plate 212 toward the base plate 211. For example, the elastic member 2222 may be a spring or another elastic structure, which is not limited in this embodiment.

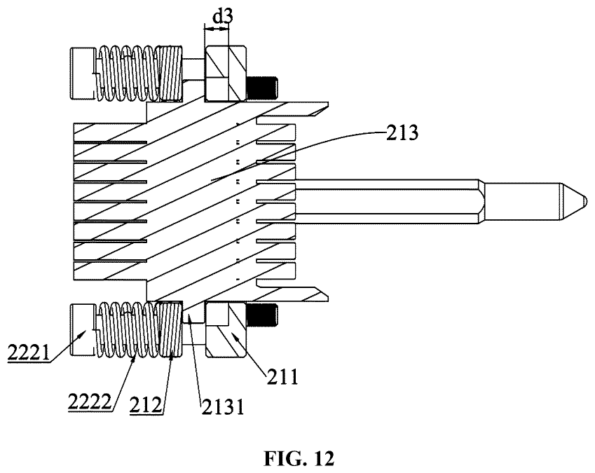

When the second floating modules 222 are in use, FIG. 11 shows the original state of the cover plate 212 and the connector body 213. At this time, the portion of the connector body 213 located between the base plate 211 and the cover plate 212 is in contact with both the base plate 211 and the cover plate 212. The movable connector 500 pushes the connector body 213 to move in the third direction Z, specifically, to move in the direction in which the cover plate 212 moves away from the base plate 211. At this time, since the connector body 213 is limited between the base plate 211 and the panel 100 in the third direction Z and the cover plate 212 can move relative to the base plate 211 under the guidance of the second connectors 2221, the connector body 213 can push the cover plate 212 to move in the direction away from the base plate 211 and compress the elastic members 2222 so that the elastic members 2222 are compressed. Since the base plate 211 cannot move relative to the panel 100, the connector body 213 can move slightly relative to the panel 100 through the second connectors 2221 until the connector body 213 moves to the state shown in FIG. 12. At this time, the portion of the connector body 213 located between the base plate 211 and the cover plate 212 is separated from the base plate 211 and is in contact with the cover plate 212. When the external force pushing the connector body 213 disappears, the cover plate 212 and the connector body 213 are pushed to return to their original positions under the elastic forces of the elastic members 2222.

It is to be noted that the maximum movement distance of the connector body 213 and the cover plate 212 in the third direction Z is related to the compression limit of the elastic members 2222. In this embodiment, as shown in FIG. 12, the maximum movement distance of the connector body 213 and the cover plate 212 in the third direction Z is a third distance d3.

In some optional embodiments, with continued reference to FIGS. 9, 11, and 12, the connector body 213 is provided with limiting portions 2131 clamped between the cover plate 212 and the base plate 211, and the cover plate 212 and the base plate 211 limit the position of the connector body 213 in the third direction Z through the limiting portions 2131. In this embodiment, at least one limiting portion 2131 is provided on each of two sides of the connector body 213 in the second direction Y to improve the limiting effect and reliability.

Optionally, the cover plate 212 and the base plate 211 limit the limiting portions 2131 in multiple manners. This embodiment provides three limiting manners below.

In the first limiting manner, as shown in FIG. 9, first grooves 2114 are provided on a surface of the base plate 211 facing the cover plate 212, the limiting portions 2131 are placed in the first grooves 2114, and the cover plate 212 is configured to cover the first grooves 2114 so that when the limiting portions 2131 move in the third direction Z, the limiting portions 2131 can push the cover plate 212 to move in the third direction Z. For example, as shown in FIG. 9, the first grooves 2114 extend to the hole wall of the second assembly hole 2121 so that the limiting portions 2131 can smoothly extend into the first grooves 2114.

In the second limiting manner, second grooves are provided on a surface of the cover plate 212 facing the base plate 211, the limiting portions 2131 are placed in the second grooves, and the base plate 211 is configured to cover the second grooves, thereby limiting the limiting portions 2131. When the limiting portions 2131 move in the third direction Z, the limiting portions 2131 can push the cover plate 212 to move in the third direction Z through the second grooves. It is to be noted that the second grooves extend to the hole wall of the first assembly hole 2111.

In the third limiting manner, third grooves are provided on a surface of the base plate 211 facing the cover plate 212, fourth grooves mating with the third grooves are provided on a surface of the cover plate 212 facing the base plate 211, a part of the limiting portion 2131 is placed in the third groove, and the other part of the limiting portion 2131 is placed in the fourth groove. That is, the third grooves and the fourth grooves mate to form cavities, and the limiting portions 2131 are placed in the cavities and can push the cover plate 212 to move in the third direction Z. It is to be noted that the third grooves extend to the hole wall of the first assembly hole 2111, and the fourth grooves extend to the hole wall of the second assembly hole 2121.

The three structures of the cover plate 212 and the base plate 211 can all limit the positions of the limiting portions 2131, thereby limiting the connector body 213 in the third direction Z.

In some optional examples, as shown in FIG. 8, the base plate 211 includes an installation region 2112 and two connection regions 2113. The two connection regions 2113 are located on two sides of the installation region 2112 in the first direction X, the first assembly hole 2111 is disposed in the installation region 2112, and the cover plate 212 and the installation region 2112 are opposite to each other in the third direction Z, that is, the connector body 213 and the cover plate 212 are both disposed in the middle of the base plate 211 in the first direction X. The length of the cover plate 212 in the first direction X is configured to be less than the length of the base plate 211 in the first direction X so that the base plate 211 has a portion that is not covered by the cover plate 212, and this portion may be used for setting the movable holes 2211, thereby facilitating the installation of the first connectors 2212, reducing the assembly difficulty of the connector module 200, and improving the assembly efficiency.

In this embodiment, with continued reference to FIG. 8, two side surfaces of the cover plate 212 are correspondingly flush with two side surfaces of the base plate 211 in the second direction Y, that is, the dimension of the cover plate 212 in the second direction Y is equal to the dimension of the base plate 211 in the second direction Y so that the connector module 200 is relatively neat in the second direction Y.

For example, multiple first floating modules 221 are provided, and at least one first floating module 221 is disposed in each of the two connection regions 2113. Specifically, the two connection regions 2113 are each provided with the movable holes 2211, and each movable hole 2211 is penetrated by the first connector 2212. In this embodiment, for each connector module 200, four first floating modules 221 are provided, and each connection region 2113 is provided with two movable holes 2211 opposite to each other in the first direction X. For example, the base plate 211 is rectangular, and each corner of the base plate 211 is provided with the movable hole 2211. Multiple first floating modules 221 are provided so that the base plate 211 can be better connected to the panel 100, thereby avoiding the rotation or deviation of the base plate 211.

In some optional examples, to ensure the floating effect of the connector body 213 in the third direction Z, with continued reference to FIG. 8, multiple second floating modules 222 are provided on two sides of the second assembly hole 2121 of the cover plate 212 in the second direction Y and are all connected to the cover plate 212 so that the uniformity of the rebound forces applied by the elastic members 2222 to the connector body 213 and the cover plate 212 can be improved, the connector body 213 can be prevented from deflecting, higher reliability can be ensured, and the reliability of the connection between the cover plate 212 and the base plate 211 can be improved. In this embodiment, the floating through holes 2223 on the cover plate 212 are distributed on two sides of the second assembly hole 2121. For example, the multiple second floating modules 222 are symmetrically disposed on the cover plate 212 with respect to an axis of symmetry extending along the first direction X, thereby further improving the uniformity of the rebound forces applied to the connector body 213 and the cover plate 212. Four, six, or eight second floating modules 222 may be provided, which is not limited in this embodiment.

In this embodiment, the multiple first floating modules 221 are disposed on two sides of the cover plate 212 in the first direction X, and the second floating modules 222 are disposed on two sides of the second assembly hole 2121 in the second direction Y so that the space on the base plate 211 and the cover plate 212 can be fully utilized, the dimensions of the connector module 200 in the first direction X and the second direction Y can be relatively small, and the density of the connector modules 200 on the cable backplane 10 can be increased, thereby increasing the communication transmission density of the cable backplane 10.

In some optional embodiments, with continued reference to FIG. 8, the connector module 200 further includes guide members 214 connected to the base plate 211 and extending from the base plate 211 in a direction away from the cover plate 212, and the guide members 214 are used for guiding the connector body 213 and the movable connector 500 when the connector body 213 and the movable connector 500 are connected through insertion so that the difficulty of connecting the connector body 213 to the movable connector 500 through insertion can be reduced, and the connector body 213 and the movable connector 500 can smoothly mate with each other through insertion. For example, an end of the guide member 214 is connected to the base plate 211, and the other end of the guide member 214 is used for penetrating a guide hole 511 of the movable connector 500, thereby facilitating the alignment of the movable connector 500 with the connector body 213. Each connector module 200 is provided with the guide members 214 so that the connector body 213 of each connector module 200 can smoothly mate with the movable connector 500 through insertion. It is to be noted that the guide members 214 pass through the panel 100 and then are inserted into guide holes 511 of the movable connector 500. Specifically, the panel 100 is provided with fifth through holes 150 corresponding to the guide members 214, and the guide members 214 pass through the fifth through holes 150 and are inserted into the guide holes 511.

Optionally, as shown in FIG. 9, the guide member 214 includes a first guide section 2141 and a second guide section 2142 that are coaxially connected. The first guide section 2141 is connected to the base plate 211. In some optional embodiments, the connection position between the first guide section 2141 and the base plate 211 is located in the connection region 2113 and avoids the movable holes 2211. In this embodiment, the cross-sectional area of the second guide section 2142 is less than the cross-sectional area of the first guide section 2141, that is, the first guide section 2141 is thicker than the second guide section 2142. The first guide section 2141 and the second guide section 2142 are provided so that step-by-step guidance can be achieved when the movable connector 500 and the connector body 213 are connected through insertion, thereby ensuring that the movable connector 500 and the connector body 213 can smoothly mate with each other through insertion. For example, the first guide section 2141 and the second guide section 2142 may both be cylindrical or nearly cylindrical structures, which is not limited in this embodiment.

Further optionally, with continued reference to FIG. 9, a tapered section 2143 is provided at an end of the second guide section 2142 facing away from the first guide section 2141. The tapered section 2143 is provided so that the guide member 214 has a pointed end, and the pointed end is located at an end of the guide member 214 facing away from the base plate 211, thereby facilitating the insertion of the guide member 214 into the guide hole 511 and further reducing the difficulty of connecting the movable connector 500 to the connector body 213.

In this embodiment, to facilitate the transition between the first guide section 2141 and the second guide section 2142, as shown in FIG. 9, a transition inclined plane 2144 is provided at the connection between the first guide section 2141 and the second guide section 2142. For example, the transition inclined plane 2144 may be a chamfer. The transition inclined plane 2144 is configured to be the chamfer so that the jamming between the first guide section 2141 and the movable connector 500 during the insertion process can be avoided, thereby improving the success rate of inserting the guide member 214 into the guide hole 511.

In this embodiment, multiple guide members 214 may be connected to each base plate 211 to further improve the guidance reliability. In this embodiment, the first floating modules 221 and the guide member 214 are disposed on each of the two sides of the connector body 213 in the first direction X, the first floating modules 221 and the guide member 214 located on the same side of the connector body 213 are arranged at intervals in the second direction Y to avoid interference, and the second floating modules 222 are disposed on each of the two sides of the connector body 213 in the second direction Y so that the first floating modules 221, the second floating modules 222, and the guide members 214 do not interfere with each other. For example, two guide members 214 are connected to each base plate 211, and the two guide members 214 are connected to two connection regions 2113, respectively.

In some optional embodiments, the circumferential side surfaces of the first guide section 2141 include at least two arc surfaces (not shown in the figure) and at least one flat surface (not shown in the figure), where the arc surfaces are used for being in contact with the hole wall of the guide hole 511, and a gap exists between the flat surface and the hole wall of the guide hole 511.

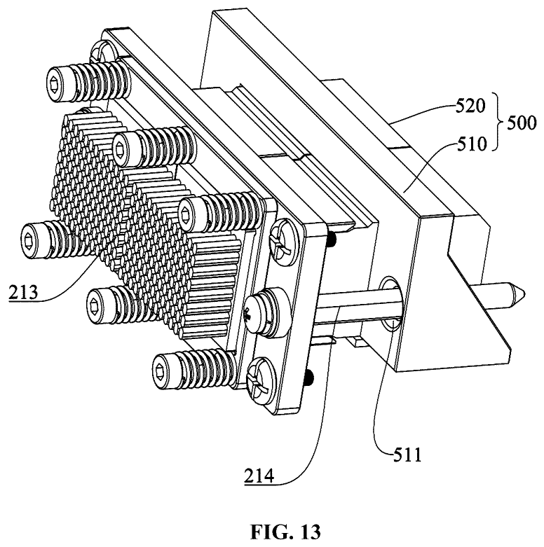

This embodiment provides the movable connector 500 for mating with the connector body 213 through insertion. As shown in FIG. 13, the movable connector 500 mates with the connector body 213 through insertion.

For example, as shown in FIG. 13, the movable connector 500 includes a fixing plate 510 and a connector body portion 520 mounted on the fixing plate 510. The connector body portion 520 is plug-fitted with the connector body 213.

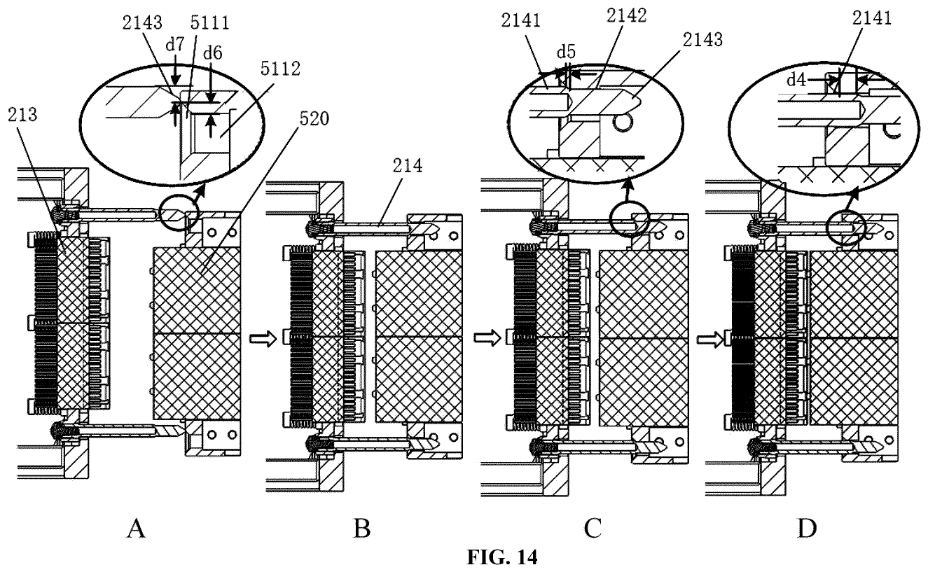

As shown in FIGS. 13 and 14, the fixing plate 510 is provided with the guide holes 511, and the guide hole 511 includes a tapered hole section 5111 and a pilot hole section 5112 that are connected and coaxially arranged. The tapered hole section 5111 is closer to the panel 100 than the pilot hole section 5112, the guide member 214 is inserted into the tapered hole section 5111 and the pilot hole section 5112, and the circumferential side surface of the guide member 214 is in contact with the hole wall of the pilot hole section 5112, thereby achieving the purpose of guiding. For example, the length of the pilot hole section 5112 in this embodiment is greater than or equal to 3 mm. For example, the length of the pilot hole section is a preset length d4. d4=3 mm, 4 mm, 4.5 mm, 5 mm, 6 mm, or the like, which is not limited in this embodiment. FIG. 14 of this embodiment further shows the distance d6 between the edge of the tapered hole section 5111 and the edge of the pilot hole section 5112, the radius d7 of the tapered section 2143, and the axial length d5 of the transition inclined plane 2144. The magnitudes of d5, d6, and d7 may be determined according to actual requirements and are not limited in this embodiment.

FIG. 14 is a schematic view illustrating step-by-step guidance performed by the guide members 214. FIG. A in FIG. 14 shows the first-step guidance. During this process, the tapered section 2143 is aligned with the tapered hole section 5111 of the guide hole 511, the movable connector 500 continues being pushed, and the tapered section 2143 enters the guide hole 511 under the guidance of the tapered hole section 5111 until the second guide section 2142 is inserted into the pilot hole section 5112 of the guide hole 511. FIG. B in FIG. 14 shows the state after the first-step guidance. After the first-step guidance, the tolerance between the connector body portion 520 of the movable connector 500 and the connector body 213 is ±0.65 (that is, 0.5*(6.3−5)). That is, in this embodiment, the diameter of the second guide section 2142 and the aperture of the guide hole 511 satisfy the tolerance between the connector body portion 520 of the movable connector 500 and the connector body 213 after the first-step guidance, where the tolerance is ±0.65 (for example, 0.5*(6.3−5)). FIG. C in FIG. 14 shows the second-step guidance. In this process, under the action of the transition inclined plane 2144, the first guide section 2141 smoothly enters the pilot hole section 5112. The diameter of the first guide section 2141 and the aperture of the pilot hole section 5112 satisfy the tolerance between the connector body portion 520 of the movable connector 500 and the connector body 213 after the second-step guidance, where the tolerance is ±0.15 (for example, 0.5*(6.3−6)). FIG. D in FIG. 14 shows the state after the second-step guidance. At this time, under the action of the first floating modules 221, the connector body 213 and the connector body portion 520 can mate with each other through insertion.

Of course, it is to be understood that the movable connector 500 may be a connector with another structure, which is not limited in this embodiment.

The panel 100 in the related art is usually an integrated structure and has a problem of a large cumulative tolerance. This embodiment provides the panel 100. As shown in FIGS. 4 and 5, the panel 100 has a spliced structure, and the panel 100 includes multiple plates 120 connected end to end. Each plate 120 is provided with multiple mounting holes 110 arranged at intervals along the length direction (that is, the second direction Y) of the plate 120.

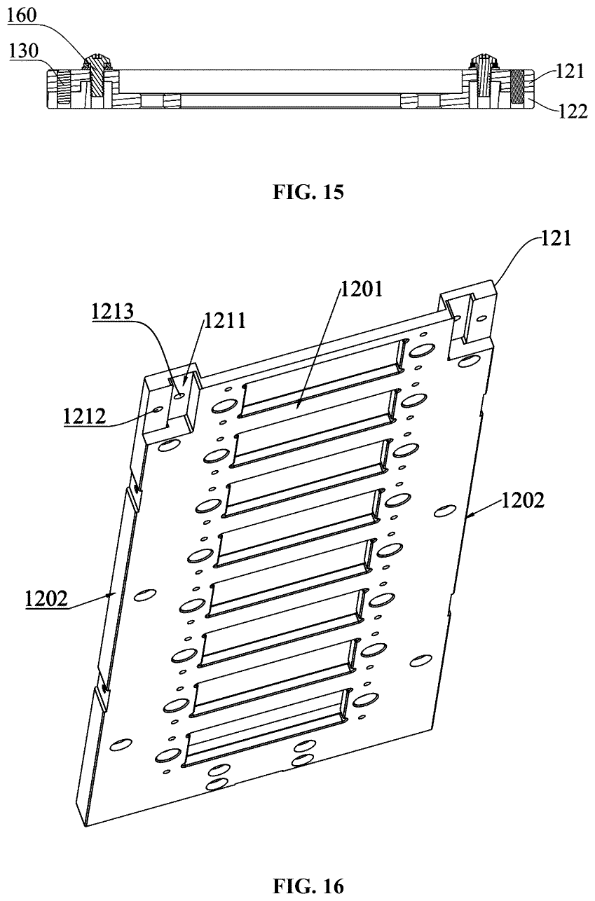

As shown in FIG. 15, first connecting portions 121 are provided on the first one of two connected plates 120, and second connecting portions 122 are provided on the second one of the two connected plates 120. The first one and the second one each represent one plate 120. The first connecting portion 121 and the second connecting portion 122 are opposite to each other in the thickness direction (that is, the third direction Z) of the plate 120.

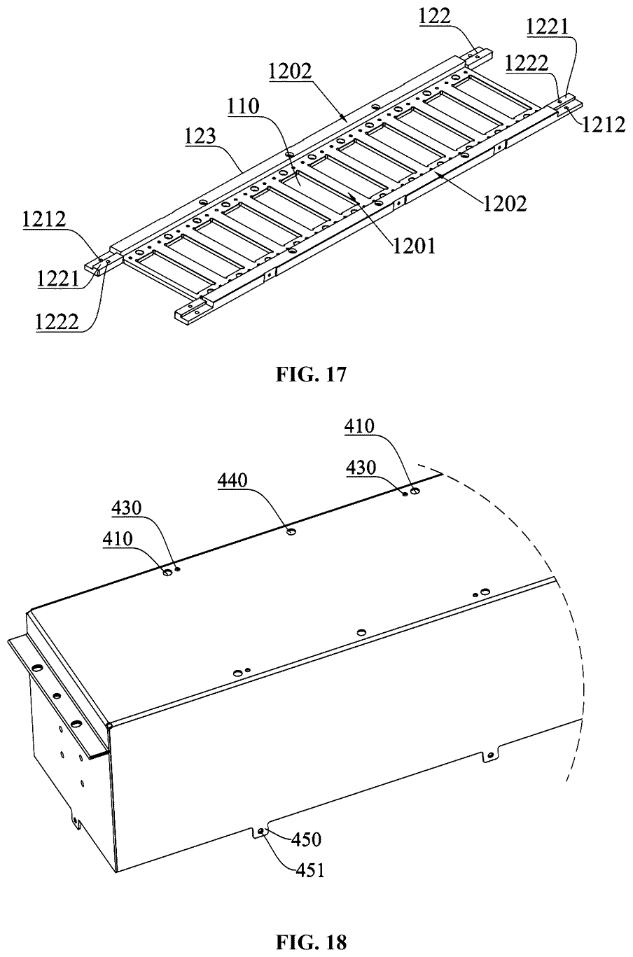

In this embodiment, as shown in FIG. 16, a pre-mounted groove 1211 is provided on a surface of the first connecting portion 121 facing the second connecting portion 122; and as shown in FIG. 17, a pre-mounted protrusion 1221 is provided on a surface of the second connecting portion 122 facing the first connecting portion 121. The pre-mounted protrusion 1221 is placed in the pre-mounted groove 1211 so that two plates 120 that need to be connected can be pre-mounted. Moreover, pre-mounted protrusions 1221 and pre-mounted grooves 1211 are provided so that the relative positions of the two plates 120 can be limited, and the two plates 120 can be accurately assembled.

For example, the first connecting portion 121 and the second connecting portion 122 are each provided with a positioning hole 1212, a positioning pin 130 passes through two positioning holes 1212, and the positioning pin 130 is used for positioning the first connecting portion 121 and the second connecting portion 122, thereby further ensuring the position accuracy of the two plates 120, that is, the connector accuracy. In this embodiment, the first connecting portions 121 and the second connecting portions 122 are connected via third connectors 160, thereby achieving the connection between the two plates 120.

The panel 100 provided in this embodiment is formed by connecting multiple plates 120 end to end, each plate 120 is provided with the mounting holes 110 for mounting the connector bodies 213, the plates 120 are provided with the first connecting portions 121 and the second connecting portions 122, two plates 120 can be connected through the first connecting portions 121 and the second connecting portions 122, the pre-mounted protrusions 1221 of the second connecting portions 122 are placed in the pre-mounted grooves 1211 of the first connecting portions 121, and the positioning pins 130 are inserted into the positioning holes 1212 of the first connecting portions 121 and the second connecting portions 122 so that the first connecting portions 121 and the second connecting portions 122 can be connected accurately, thereby ensuring the connection accuracy of the two plates 120. Each plate 120 does not need to be set longer, thereby avoiding the case where the connector bodies 213 cannot mate with the movable connectors 500 through insertion due to a relatively large cumulative tolerance of the mounting holes 110. In this manner, multiple connector bodies 213 can simultaneously mate with multiple movable elements through insertion, and the reliability of the cable backplane 10 adopting the panel can be improved. The plate 120 is relatively short so that the case where the plate 120 bends in the middle can be avoided, thereby avoiding the problem that the connector body 213 set in the middle of the panel 100 in the length direction cannot be connected to the movable connector 500 and improving the yield and reliability of the cable backplane 10 adopting the panel 100.

By providing the spliced panel 100 and mating with the floating assembly 220, the cable backplane 10 provided in this embodiment can be applied to the plug-in box 30 with a larger assembly tolerance based on a smaller assembly tolerance of the cable backplane 10 so that the cable backplane 10 has stronger adaptability and thus can have a lower cost.

In this embodiment, the cross sections of the first connecting portion 121 and the second connecting portion 122 are both “Z”-shaped so that the first connecting portion 121 and the second connecting portion 122 can mate with each other to achieve accurate connection.

Optionally, as shown in FIGS. 16 and 17, each plate 120 includes a middle region 1201 and frame regions 1202 disposed on two sides of the middle region 1201 along the width direction (that is, the first direction X) of the plate 120. The thickness of the plate 120 in the middle region 1201 is less than that in the frame regions 1202, and the mounting holes 110 are formed in the middle region 1201. By setting the middle region 1201 with a smaller thickness and mounting the connector body 213 in the middle region 1201, on the basis of ensuring the support for the connector body 213, the sum of the thickness of the middle region 1201 and the thickness of the connector module 200 may be relatively small so that the overall thickness of the cable backplane 10 can be relatively small, thereby making the overall dimension of the cable backplane 10 relatively small, which is conducive to the application of the cable backplane 10 in application scenarios with relatively high space requirements.

It is to be noted that each frame region 1202 is provided with the first connecting portion 121 and/or the second connecting portion 122, that is, the first connecting portion 121 and the second connecting portion are disposed in the frame region 1202. Since the thickness of the frame region 1202 is relatively large, the thickness of the first connecting portion 121 and the thickness of the second connecting portion 122 may both be relatively large, which is conducive to forming the pre-mounted groove 1211.

In some optional embodiments, referring to FIG. 4 and FIGS. 15 to 17, the portion of the frame region 1202 where the first connecting portion 121 and the second connecting portion 122 are not provided is a body portion 123, that is, each frame region 1202 includes the body portion 123 and the first connecting portion 121, or includes the body portion 123 and the second connecting portion 122, or includes the body portion 123, the first connecting portion 121, and the second connecting portion 122. The sum of the thickness of the first connecting portion 121 and the thickness of the second connecting portion 122 is equal to the thickness of the body portion 123, a surface of the first connecting portion 121 facing away from the second connecting portion 122 is flush with a side surface of the body portion 123 in the thickness direction, and a surface of the second connecting portion 122 facing away from the first connecting portion 121 is flush with the other side surface of the body portion 123 in the thickness direction so that the setting of the first connecting portion 121 and the second connecting portion 122 does not increase the thickness of the plate 120, which is further conducive to the thinning and lightening of the panel 100. Moreover, the surface of the first connecting portion 121 facing away from the second connecting portion 122 is flush with a side surface of the body portion 123 in the thickness direction, and the surface of the second connecting portion 122 facing away from the first connecting portion 121 is flush with the other side surface of the body portion 123 in the thickness direction, thereby facilitating the assembly of components on two sides of the panel 100 and making the panel 100 relatively neat.

For example, the length of the first connecting portion 121 is equal to the length of the second connecting portion 122. Moreover, as shown in FIG. 4, the end surface of the first connecting portion 121 is in contact with the end surface of the second one, and the end surface of the second connecting portion 122 is in contact with the end surface of the first one so that the first connecting portion 121 and the second connecting portion 122 can be better fitted together, the risk of relative movement between the first connecting portion 121 and the second connecting portion 122 when the panel 100 is subjected to a force in the thickness direction can be avoided, the panel 100 can be prevented from bending and deforming, the integrity of the panel 100 can be improved, and the panel 100 can better support the connector modules 200. It is to be noted that the length direction of the first connecting portion 121 is the same as the length direction of the second connecting portion 122. For example, the length direction of the first connecting portion 121 is the second direction Y.

In some optional embodiments, the pre-mounted groove 1211 extends to the end surface of the first connecting portion 121. Specifically, the pre-mounted groove 1211 extends to the end of the first connecting portion 121 in the second direction Y. On the one hand, the dimension of the pre-mounted groove 1211 is larger so that it is convenient to assemble the pre-mounted groove 1211 and the pre-mounted protrusion 1221. On the other hand, the pre-mounted protrusion 1221 may be inserted into the pre-mounted groove 1211 from the end of the first connecting portion 121, thereby further facilitating the assembly of two plates 120. Similarly, the pre-mounted protrusion 1221 extends to the end surface of the second connecting portion 122, that is, the pre-mounted protrusion 1221 extends to the end of the second connecting portion 122 in the second direction Y so that the pre-mounted protrusion 1221 can slide into the pre-mounted groove 1211.

Optionally, as shown in FIG. 16, the first connecting portion 121 is provided with a through hole 1213, the second connecting portion 122 is provided with a second threaded hole 1222, the third connector 160 is a bolt, and the bolt passes through the through hole 1213 and is screwed to the second threaded hole 1222 so that the first connecting portion 121 and the second connecting portion 122 can be connected. In this embodiment, as shown in FIGS. 16 and 17, the through hole 1213 is disposed in the pre-mounted groove 1211, the second threaded hole 1222 is disposed in the pre-mounted protrusion 1221, and the positioning holes 1212 are located outside the pre-mounted groove 1211 and the pre-mounted protrusion 1221 so that the positioning holes 1212 are separated from the through hole 1213, that is, the positioning holes 1212 are separated from the second threaded hole 1222, thereby reducing the influence of the holes on the structural strength of the first connecting portion 121 and the second connecting portion 122.

In some optional embodiments, as shown in FIG. 4, the widths of the multiple plates 120 are the same, that is, the lengths of the multiple plates 120 in the first direction X are equal, thereby ensuring the neatness of the structure of the panel 100 in the first direction X. Moreover, as shown in FIG. 5, shallow grooves 124 are provided on two sides of the plate 120 in the length direction and/or two sides of the plate 120 in the width direction, and a third threaded hole 1241 is provided at the bottom of the shallow groove 124. For example, the shallow grooves 124 are used for connecting other structures.

With continued reference to FIG. 4, three plates 120 are provided, that is, the panel 100 includes three plates 120, which are a first plate 12a, a second plate 12b, and a third plate 12c, respectively. The first plate 12a, the second plate 12b, and the third plate 12c are connected in sequence along the second direction Y.

In the second direction Y, an end of the first plate 12a and an end of the third plate 12c are each provided with the first connecting portions 121, and neither the other end of the first plate 12a nor the other end of the third plate 12c is provided with the first connecting portions 121 or the second connecting portions 122. For example, as shown in FIG. 16, two first connecting portions 121 are provided at an end of the first plate 12a. Of course, two first connecting portions 121 are also provided at an end of the third plate 12c. The second connecting portions 122 are provided at each of the two ends of the second plate 12b. As shown in FIG. 17, two second connecting portions 122 are provided at each of the two ends of the second plate 12b. The first connecting portions 121 of the first plate 12a are connected to the second connecting portions 122 at an end of the second plate 12b through the third connectors 160, and the first connecting portions 121 of the third plate 12c are connected to the second connecting portions 122 at the other end of the second plate 12b through the third connectors 160 so that the first plate 12a, the second plate 12b, and the third plate 12c can be connected.

In some optional embodiments, as shown in FIG. 4, the length of the mounting holes 110 on the second plate 12b in the width direction (that is, the first direction X) of the plate 120 is greater than the length of the mounting holes 110 on the first plate 12a in the width direction of the plate 120 and greater than the length of the mounting holes 110 on the third plate 12c in the width direction of the plate 120 so that the dimensions of the connector bodies 213 mounted on the second plate 12b in the first direction X can be larger, and the panel 100 can be suitable for mounting the connector bodies 213 of different dimensions, thereby further improving the flexibility of the panel 100.

As shown in FIGS. 1 to 3, the cable backplane 10 further includes a housing 400, and an opening 420 is provided on a side of the housing 400. Specifically, the opening 420 is provided on a side of the housing 400 in the third direction Z. The panel 100 is disposed at the opening 420 and connected to the housing 400. The housing 400 and the panel 100 surround a relatively sealed space. Part of the connector bodies 213 and wires are located in the space. The housing 400 is used for dust prevention and waterproofing.

In some optional embodiments, as shown in FIG. 18, the housing 400 is provided with multiple tabs 450. The tabs 450 are disposed on a side of the housing 400, the tabs 450 correspond to the shallow grooves 124 on the plates 120, that is, the number of the tabs 450 is the same as the number of the shallow grooves 124, and the tabs 450 are placed in the corresponding shallow grooves 124 so that the shallow grooves 124 can accommodate the tabs 450, and the dimension of the cable backplane 10 in the first direction X or the second direction Y does not increase due to the provided tabs 450, which is conducive to the miniaturization of the cable backplane 10. The tab 450 is provided with a tab through hole 451 connecting with the third threaded hole 1241. A fourth bolt passes through the third threaded hole 1241 and the tab through hole 451 to connect the tab 450 to the plate 120, thereby achieving the connection between the housing 400 and the panel 100. The tabs 450 are provided so that the housing 400 does not need to be provided with a circumferential edge protruding from the panel 100, thereby reducing the materials used for the housing 400 and the weight of the housing 400, which is conducive to the lightweight of the cable backplane 10.

Optionally, the cable backplane 10 further includes vertical plate assemblies 300. The vertical plate assemblies 300 are connected to the panel 100, are used for connecting the panel 100 to a cabinet body 20 of a communication device, and have relatively strong connection strength and a relatively low weight.

In some optional embodiments, the vertical plate assemblies 300 are located in the housing 400, the vertical plate assembly 300 is provided with first threaded holes 311, the housing 400 is provided with first through holes 410 connecting with the first threaded holes 311, an end of a first bolt passes through the first through hole 410 and is screwed to the first threaded hole 311, and the other end of the first bolt is connected to the cabinet body 20 of the cabinet so that the panel 100 can be connected to the cabinet body 20 through the vertical plate assemblies 300.

For example, the opening 420 is disposed on a side of the housing 400 in the third direction Z. As shown in FIG. 18, multiple first through holes 410 are disposed on a wall surface of the other side of the housing 400. Multiple vertical plates 310 are provided in the housing 400. An end of the vertical plate 310 is connected to the panel 100, the other end of the vertical plate 310 is provided with the first threaded holes 311, the multiple first through holes 410 are in one-to-one correspondence with the multiple first threaded holes 311, an end of the first bolt passes through the first through hole 410 and is connected to the first threaded hole 311, and the other end of the first bolt is used for connecting the cabinet body 20 of the cabinet.

In this embodiment, multiple vertical plates 310 are provided, and the connection between the cabinet body 20 and the panel 100 is achieved through the vertical plates 310. Compared with the connection manner of the housing 400 and the cabinet body 20 in the related art, the strength requirement for the housing 400 can be lower, and the strength requirement for the housing 400 is transferred to the vertical plates 310. Since only a few vertical plates 310 are required, even if thicker vertical plates 310 with better materials are used, the cost of the cable backplane 10 does not increase too much, the overall weight of the cable backplane 10 is less affected, and the reliability of the connection between the panel 100 and the cabinet body 20 can be improved. Moreover, the vertical plates 310 are provided to support the housing 400 so that the housing 400 can be prevented from deforming due to the impact or compression by other components, and the connector bodies 213, wires, or other electronic components inside the housing 400 can be better protected, thereby achieving higher safety.

It is to be noted that each vertical plate 310 may be provided with multiple first threaded holes 311 to improve the connection strength between each vertical plate 310 and the cabinet body 20, and the number of the first bolts and the number of the first through holes 410 correspond to the number of the first threaded holes 311.

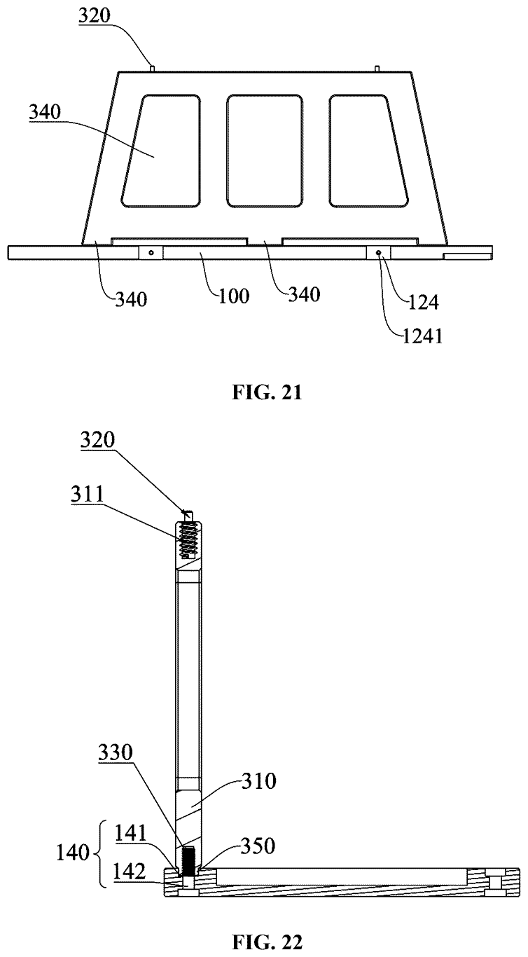

In some optional examples, with continued reference to FIG. 18, the housing 400 is further provided with second through holes 430. As shown in FIGS. 20 and 21, positioning columns 320 are provided at an end of the vertical plate 310 facing away from the panel 100, that is, the positioning columns 320 are provided at an end of the vertical plate 310 where the first threaded holes 311 are provided. An end of the positioning column 320 facing away from the vertical plate 310 passes through the second through hole 430 and is used for being inserted into a mating hole of the cabinet body 20 so that the cabinet body 20 and the vertical plates 310 can be positioned, the cabinet body 20 and the entire cable backplane 10 can be positioned, and the cable backplane 10 can be mounted at a preset position on the cabinet body 20.

For example, one or more positioning columns 320 may be provided, and each positioning column 320 may correspond to the second through hole 430.

In some optional embodiments, as shown in FIG. 22, the panel 100 is provided with multiple third through holes 140, each vertical plate 310 is provided with fourth threaded holes 330 corresponding to and connecting with the third through holes 140, and a second bolt (not shown in the figure) passes through the third through hole 140 and is connected to the fourth threaded hole 330 to achieve the connection between the vertical plate 310 and the panel 100.

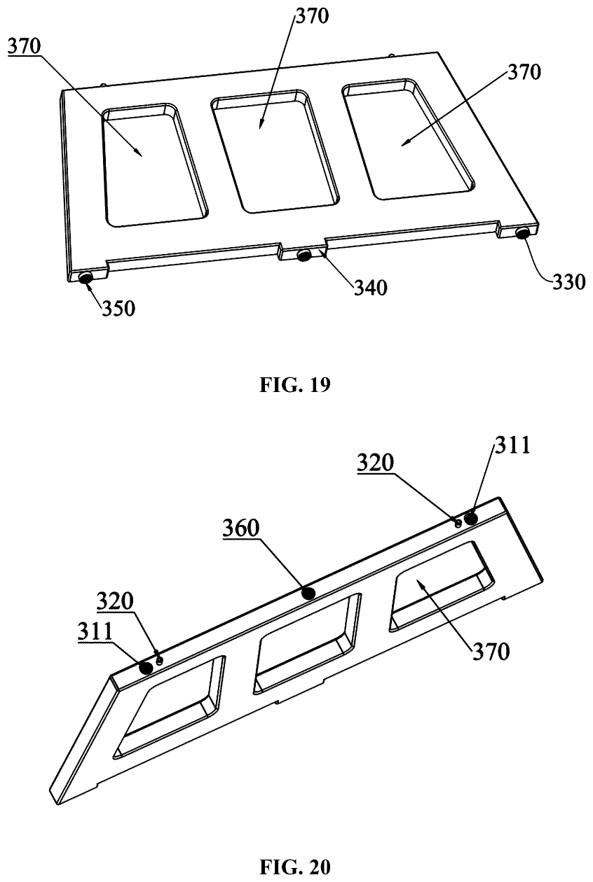

Further optionally, as shown in FIG. 19, multiple supporting protrusions 340 are provided at an end of the vertical plate 310 facing the panel 100, that is, the supporting protrusions 340 are provided on an end surface of the vertical plate 310 facing the panel 100. The multiple supporting protrusions 340 are arranged at intervals along the length direction (that is, the second direction Y) of the panel 100. As shown in FIG. 21, the supporting protrusions 340 are in contact with the panel 100. Specifically, the supporting protrusions 340 fit the panel 100. The fourth threaded hole 330 is disposed on the supporting protrusion 340 to facilitate the connection between the vertical plate 310 and the panel 100. The supporting protrusions 340 are provided so that the supporting protrusions, the panel 100, and a surface of the vertical plate 310 facing the panel 100 can surround a hole structure so that the overall weight of the vertical plate 310 can be smaller, which is conducive to the miniaturization of the cable backplane 10. For example, as shown in FIG. 21, three supporting protrusions 340 are provided at intervals.

In some optional embodiments, to further facilitate the connection between the vertical plate 310 and the panel 100, a protruding column 350 is provided on a surface of each supporting protrusion 340 facing away from the vertical plate 310, that is, the protruding column 350 is disposed on the supporting protrusion 340. For example, the protruding column 350 and the supporting protrusion 340 are coaxially arranged. As shown in FIG. 22, the third through hole 140 includes a large hole section 141 and a small hole section 142 that are coaxially arranged, the protruding column 350 is placed in the large hole section 141, and the supporting protrusion 340 is in contact with the panel 100. The protruding columns 350 are inserted into the large hole sections 141 so that the vertical plate 310 can be pre-mounted on the panel 100, that is, before the second bolts are connected, each protruding column 350 is inserted into the corresponding large hole section 141, thereby pre-fixing each vertical plate 310. The fourth threaded hole 330 extends to the protruding column 350, and the second bolt can be directly screwed into the protruding column 350 from the front side of the panel 100 and extend into the supporting protrusion 340 or even the vertical plate 310.

For example, the third through hole 140 further includes an accommodation groove disposed at an end of the small hole section 142 facing away from the large hole section 141, and the accommodation groove is used for accommodating the cap of the second bolt to prevent the cap of the second bolt from protruding from the front side of the panel 100, thereby affecting the connection between the connector body 213 and the movable connector 500 through insertion.

For example, as shown in FIG. 3, the vertical plates 310 are connected to two edges of the panel 100 in the width direction, that is, the vertical plates 310 are connected to the frame regions 1202 of the plate 120. In this embodiment, each frame region 1202 of each plate 120 is connected to a corresponding vertical plate 310 so that each plate 120 can be connected to the cabinet body 20 through the vertical plates 310, thereby reducing the dependence on the connection strength between the plates 120. The vertical plates 310 are connected to the frame regions of the plate 120 so that the vertical plates 310 can be prevented from interfering with the connector bodies 213 and wires.

In some optional embodiments, the multiple vertical plates 310 are arranged at intervals in the length direction of the panel 100. For example, the multiple vertical plates 310 may be arranged evenly and at intervals to improve the uniformity and reliability of supporting the panel 100.

Optionally, as shown in FIG. 20, the vertical plate 310 further includes a fifth threaded hole 360. As shown in FIG. 18, the housing 400 is provided with fourth through holes 440 correspondingly connecting with fifth threaded holes 360. As shown in FIG. 3, the cable backplane 10 further includes handles 600. The handle 600 is located on the outer side of the housing 400, and third bolts pass through the fourth through holes 440 and are connected to the fifth threaded holes 360 to connect the handle 600 to the vertical plates 310. By providing the handles 600, an operator or a device such as a manipulator can grab the entire cable backplane 10 through the handles 600, thereby facilitating the movement and transportation of the cable backplane 10 and the assembly of the cable backplane 10.

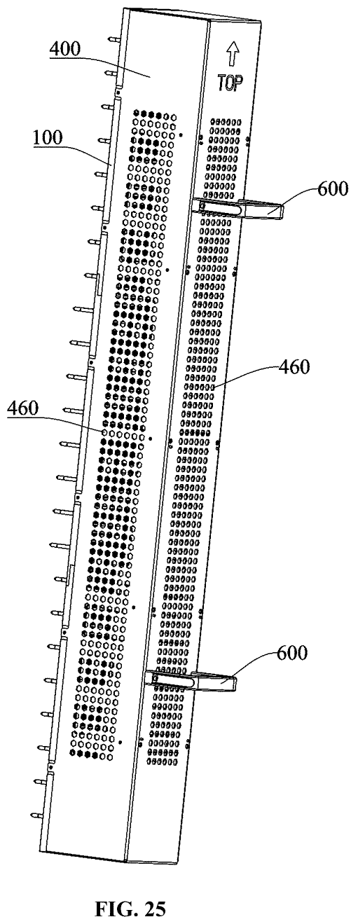

For example, as shown in FIG. 25, the housing 400 is provided with multiple heat dissipation holes 460 for heat dissipation inside the housing 400 to avoid overheating in the space surrounded by the housing 400 and the panel 100, thereby improving the usage safety and reliability of the cable backplane. It is to be noted that the housing 400 is formed by multiple side plates, and each side plate is provided with multiple heat dissipation holes 460.

In some optional embodiments, not all vertical plates 310 are connected to the handles 600. Some vertical plates 310 may each be provided with the fifth threaded hole 360, while some vertical plates 310 are not provided with the fifth threaded holes 360. In this case, some vertical plates 310 are connected to the handles 600, while the other vertical plates 310 are not connected to the handles 600, which is not limited in this embodiment. Of course, it is to be understood that each vertical plate 310 may be connected to the handle 600, which is not limited in this embodiment.

In this embodiment, the vertical plates 310 are provided on two edges of the panel 100 in the first direction X, the handle 600 has a U-shaped structure, an end of the handle 600 is connected to the vertical plate 310 on an edge of the panel 100 in the first direction X, and the other end of the handle 600 is connected to the vertical plate 310 on the other edge of the panel 100 in the first direction X so that the dimension of the handle 600 is smaller, and the forces applied to the panel 100 can be more balanced.

In some optional embodiments, as shown in FIGS. 19 and 21, the vertical plate 310 is provided with lightening holes penetrating the vertical plate 310 in the thickness direction of the vertical plate 310. The lightening holes are provided. In this manner, on the one hand, the weight of the vertical plate 310 is relatively small, which is conducive to the lightweight of the cable backplane 10; on the other hand, the heat generated by the connector bodies 213 can be transferred to the housing 400 through the lightening holes and then dissipated to the outside through the housing 400 so that the vertical plate 310 does not excessively block the heat transferred to the housing 400, which is conducive to the heat dissipation of the cable backplane 10, thereby avoiding affecting the communication efficiency due to overheating.

Optionally, one or more lightening holes may be provided, which is not limited in this embodiment.

For example, as shown in FIG. 6, an end surface of the vertical plate 310 facing away from the panel 100 is in contact with the housing 400 so that the housing 400 can be better supported, the housing 400 can be prevented from twisting and deforming, and the appearance of the cable backplane can be ensured.

In some optional embodiments, the vertical plate 310 is a trapezoidal plate, a rectangular plate, a square plate, or a plate of another shape, which is not limited in this embodiment. In this embodiment, the vertical plate 310 is a trapezoidal plate, the longer end of the trapezoidal plate is in contact with the panel 100, and the shorter end of the trapezoidal plate is in contact with the housing 400.

In a second aspect, this embodiment further provides a communication device including the cable backplane 10 in the first aspect. The communication device provided in this embodiment has a better communication effect and a wider range of application scenarios.

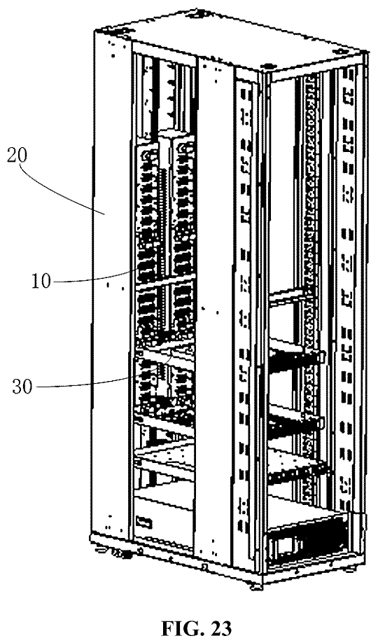

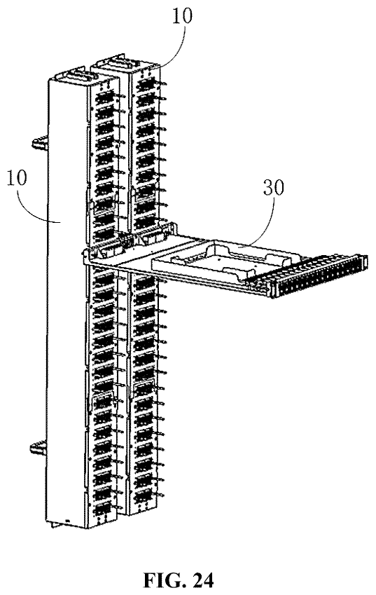

The communication device in this embodiment may be the cabinet. Of course, the communication device may be another electronic component, which is not limited in this embodiment. FIG. 23 is a schematic view illustrating that the communication device is the cabinet according to this embodiment, where two cable backplanes 10 are provided and connected to the cabinet body 20 of the cabinet, and three plug-in boxes 30 are provided and connected to the cable backplanes through insertion. FIG. 24 is a schematic view illustrating that two cable backplanes 10 and one plug-in box 30 mate with each other through insertion according to this embodiment.

It is to be noted that the preceding are only preferred embodiments of the present disclosure and the technical principles used therein. It is to be understood by those skilled in the art that the present disclosure is not limited to the embodiments described herein. Those skilled in the art can make various apparent modifications, adaptations, and substitutions without departing from the scope of the present disclosure. Therefore, while the present disclosure is described in detail through the preceding embodiments, the present disclosure is not limited to the preceding embodiments and may include more other equivalent embodiments without departing from the concept of the present disclosure. The scope of the present disclosure is determined by the scope of the appended claims.

What is claimed is:

1. A cable backplane, comprising:
a panel provided with a plurality of mounting holes; and
a plurality of connector modules provided in one-to-one correspondence with the plurality of mounting holes, wherein each of the plurality of connector modules comprises a support assembly, a connector body, and a floating assembly, the support assembly is provided with an assembly hole connecting with a mounting hole of the plurality of mounting holes, the connector body passes through the mounting hole and the assembly hole, the support assembly is floatingly connected to the panel in a first direction and a second direction via the floating assembly, and the connector body is floatingly connected to the support assembly in a third direction via the floating assembly so that the connector body is capable of floating relative to the panel in the first direction, the second direction, and the third direction;
wherein the first direction, the second direction, and the third direction are perpendicular to each other.

2. The cable backplane of claim 1, wherein the floating assembly comprises a first floating module and a second floating module, the first floating modules is connected to the panel and the support assembly, and the support assembly floats relative to the panel in the first direction and the second direction via the first floating module; and
the second floating module is connected to the support assembly and the connector body, and the connector body floats relative to the support assembly in the third direction via the second floating module, wherein the third direction is a thickness direction of the panel.

3. The cable backplane of claim 2, wherein the support assembly comprises a base plate and a cover plate, the base plate is disposed on a side of the panel, the cover plate is disposed on a side of the base plate facing away from the panel and movably connected to the base plate, the assembly hole comprises a first assembly hole disposed on the base plate and a second assembly hole disposed on the cover plate, and the connector body is limited between the base plate and the panel in the third direction;
the first floating module comprises a movable hole and a first connector, wherein the movable hole is disposed on the base plate, the first connector passes through the movable hole and is connected to the panel, and the first connector limits movement of the base plate relative to the panel in the third direction; and
a length of a portion of the first connector located in the movable hole in the first direction is a first length, a length of the movable hole in the first direction is a second length, the first length is less than the second length, a length of a portion of the first connector located in the movable hole in the second direction is a third length, a length of the movable hole in the second direction is a fourth length, and the third length is less than the fourth length.

4. The cable backplane of claim 3, wherein the first connector and the movable hole are coaxially arranged.

5. The cable backplane of claim 2, wherein the support assembly comprises a base plate and a cover plate, the base plate is disposed on a side of the panel, the cover plate is disposed on a side of the base plate facing away from the panel and movably connected to the base plate, the assembly hole comprises a first assembly hole disposed on the base plate and a second assembly hole disposed on the cover plate, and the connector body is limited between the base plate and the panel in the third direction; and
the second floating module comprises a second connector, an elastic member, and a floating through hole, wherein the floating through hole is provided on the cover plate, the second connector is capable of sliding through the floating through hole and being connected to the base plate, a position of the base plate relative to the panel in the third direction is fixed, the elastic member is sleeved on the second connector, an end of the elastic member abuts against the cover plate, and another end of the elastic member is limited by the second connector.

6. The cable backplane of claim 2, wherein the support assembly comprises a base plate and a cover plate, the base plate is disposed on a side of the panel, the cover plate is disposed on a side of the base plate facing away from the panel and movably connected to the base plate, the assembly hole comprises a first assembly hole disposed on the base plate and a second assembly hole disposed on the cover plate, and the connector body is limited between the base plate and the panel in the third direction; and
the base plate comprises an installation region and two connection regions, wherein the two connection regions are located on two sides of the installation region in the first direction, the first assembly hole is disposed in the installation region, the cover plate and the installation region are opposite to each other, two side surfaces of the cover plate are correspondingly flush with two side surfaces of the base plate in the second direction, a plurality of first floating modules are provided, and at least one of the plurality of first floating modules is disposed in each of the two connection regions.

7. The cable backplane of claim 6, wherein a plurality of second floating modules are provided on two sides of the second assembly hole in the second direction and are all connected to the cover plate.

8. The cable backplane of claim 1, further comprising vertical plate assemblies connected to the panel and used for connecting the panel to a cabinet body of a communication device.

9. The cable backplane of claim 8, further comprising a housing mounted on a side of the panel, wherein the vertical plate assemblies are located in the housing, a vertical plate assembly of the vertical plate assemblies is provided with a first threaded hole, the housing is provided with a first through hole connecting with the first threaded hole, an end of a first bolt passes through the first through hole and is screwed to the first threaded hole, and another end of the first bolt is connected to the cabinet body of a cabinet.

10. A communication device, comprising a cable backplane,
wherein the cable backplane comprises:
a panel provided with a plurality of mounting holes; and
a plurality of connector modules provided in one-to-one correspondence with the plurality of mounting holes, wherein each of the plurality of connector modules comprises a support assembly, a connector body, and a floating assembly, the support assembly is provided with an assembly hole connecting with a mounting hole of the plurality of mounting holes, the connector body passes through the mounting hole and the assembly hole, the support assembly is floatingly connected to the panel in a first direction and a second direction via the floating assembly, and the connector body is floatingly connected to the support assembly in a third direction via the floating assembly so that the connector body is capable of floating relative to the panel in the first direction, the second direction, and the third direction;
wherein the first direction, the second direction, and the third direction are perpendicular to each other.

11. The communication device of claim 10, wherein the floating assembly comprises a first floating module and a second floating module, the first floating modules is connected to the panel and the support assembly, and the support assembly floats relative to the panel in the first direction and the second direction via the first floating module; and
the second floating module is connected to the support assembly and the connector body, and the connector body floats relative to the support assembly in the third direction via the second floating module, wherein the third direction is a thickness direction of the panel.

12. The communication device of claim 11, wherein the support assembly comprises a base plate and a cover plate, the base plate is disposed on a side of the panel, the cover plate is disposed on a side of the base plate facing away from the panel and movably connected to the base plate, the assembly hole comprises a first assembly hole disposed on the base plate and a second assembly hole disposed on the cover plate, and the connector body is limited between the base plate and the panel in the third direction;
the first floating module comprises a movable hole and a first connector, wherein the movable hole is disposed on the base plate, the first connector passes through the movable hole and is connected to the panel, and the first connector limits movement of the base plate relative to the panel in the third direction; and
a length of a portion of the first connector located in the movable hole in the first direction is a first length, a length of the movable hole in the first direction is a second length, the first length is less than the second length, a length of a portion of the first connector located in the movable hole in the second direction is a third length, a length of the movable hole in the second direction is a fourth length, and the third length is less than the fourth length.

13. The communication device of claim 12, wherein the first connector and the movable hole are coaxially arranged.

14. The communication device of claim 11, wherein the support assembly comprises a base plate and a cover plate, the base plate is disposed on a side of the panel, the cover plate is disposed on a side of the base plate facing away from the panel and movably connected to the base plate, the assembly hole comprises a first assembly hole disposed on the base plate and a second assembly hole disposed on the cover plate, and the connector body is limited between the base plate and the panel in the third direction; and
the second floating module comprises a second connector, an elastic member, and a floating through hole, wherein the floating through hole is provided on the cover plate, the second connector is capable of sliding through the floating through hole and being connected to the base plate, a position of the base plate relative to the panel in the third direction is fixed, the elastic member is sleeved on the second connector, an end of the elastic member abuts against the cover plate, and another end of the elastic member is limited by the second connector.

15. The communication device of claim 11, wherein the support assembly comprises a base plate and a cover plate, the base plate is disposed on a side of the panel, the cover plate is disposed on a side of the base plate facing away from the panel and movably connected to the base plate, the assembly hole comprises a first assembly hole disposed on the base plate and a second assembly hole disposed on the cover plate, and the connector body is limited between the base plate and the panel in the third direction; and
the base plate comprises an installation region and two connection regions, wherein the two connection regions are located on two sides of the installation region in the first direction, the first assembly hole is disposed in the installation region, the cover plate and the installation region are opposite to each other, two side surfaces of the cover plate are correspondingly flush with two side surfaces of the base plate in the second direction, a plurality of first floating modules are provided, and at least one of the plurality of first floating modules is disposed in each of the two connection regions.

16. The communication device of claim 15, wherein a plurality of second floating modules are provided on two sides of the second assembly hole in the second direction and are all connected to the cover plate.

17. The communication device of claim 10, further comprising vertical plate assemblies connected to the panel and used for connecting the panel to a cabinet body of a communication device.

18. The communication device of claim 17, further comprising a housing mounted on a side of the panel, wherein the vertical plate assemblies are located in the housing, a vertical plate assembly of the vertical plate assemblies is provided with a first threaded hole, the housing is provided with a first through hole connecting with the first threaded hole, an end of a first bolt passes through the first through hole and is screwed to the first threaded hole, and another end of the first bolt is connected to the cabinet body of a cabinet.
